(19) United States
(12) Patent Application Publication
(10) Pub. No.: US 2011/0090651 A1
(43) Pub. Date: Apr. 21, 2011

(54) PACKAGE STRUCTURE

(75) Inventors: Sunghae Jung, Daejeon (KR); Dong Suk Jun, Daejeon (KR); Jong Tae Moon, Chungcheongnam-do (KR); Hyun-cheol Bae, Daejeon (KR); Moo Jung Chu, Daejeon (KR)

(73) Assignee: ELECTRONICS AND TELECOMMUNICATIONS RESEARCH INSTITUTE, Daejeon (KR)

(21) Appl. No.: 12/765,619

(22) Filed: Apr. 22, 2010

(30) Foreign Application Priority Data
Oct. 15, 2009 (KR) 10-2009-0098237

(51) Int. Cl. H05K 7/00

(52) U.S. Cl. 361/748

(57) ABSTRACT

Provided is a package structure. The package structure includes a first substrate, a first device, a second substrate, a first via contact, and at least one second device. The first device is formed on the first substrate. The second substrate has an air gap over the first substrate and covers the first device. The first via contact is connected to the first device through the second substrate. At least one second device is electrically connected to the first via contact, and is stacked on the second substrate.

### CROSS-REFERENCE TO RELATED APPLICATIONS

This U.S. non-provisional patent application claims priority under 35 U.S.C. §119 of Korean Patent Application No. 10-2009-0098237, filed on Oct. 15, 2009, the entire contents of which are hereby incorporated by reference.

### BACKGROUND OF THE INVENTION

The present invention disclosed herein relates to a package structure, and more particularly, to a package structure having a plurality of devices stacked therein.

High-performance RF devices such as Film Bulk Acoustic Resonators (FBAR) are realized by Micro Electro-Machinery System (MEMS) technologies. The FBAR may be manufactured as a module of a filter by being mounted onto a Printed Circuit Board (PCB) after being manufactured in a separate substrate. Here, since respective devices are connected through a bonding wire in every case, parasitic components may be generated. Moreover, as an inductor is mounted onto a PCB, it is difficult to implement high inductance, and an increase of the total size becomes an obstacle to implementation of a micromini and high performance filter.

To overcome these limitations, a FBAR and an inductor may be designed to be disposed on a single substrate. However, since two devices are disposed on the same plane, the size of the plane may be increased.

### SUMMARY OF THE INVENTION

The present invention provides a package structure, which can implement a micromini product by minimizing a variation of a planar area according to increase and decrease of sizes of an FBAR and an inductor.

Embodiments of the present invention provide package structures including: a first substrate; a first device on the first substrate; a second substrate having an air gap over the first substrate and covering the first device; a first via contact connected to the first device through the second substrate; and at least one second device electrically connected to the first via contact and stacked on the second substrate.

In some embodiments, the package structures may further include a contact pad connecting the first device and the first via contact between the first substrate and the second substrate. The contact pad may be electrically connected to an upper electrode and a lower electrode of the first device formed on the first substrate. Accordingly, the first and second devices stacked on the first and second substrate, respectively, may be electrically connected through the via contact and the contact pad.

In other embodiments, the first device may include a resonator, and the second device may include at least one of an inductor or a first phase shifter. Accordingly, a filter including the resonator, the inductor, and the first phase shifter may be implemented.

In still other embodiments, the package structures may further include an insulating layer electrically isolating the inductor from the first phase shifter. The first phase shifter and the inductor formed on the capping substrate may be stacked while being electrically isolated by the insulating layer.

In even other embodiments, the package structures may further include a second via contact electrically connecting the first phase shifter and the inductor to the first via contact and exposed on an upper part of the insulating layer.

In yet other embodiments, the package structures may further include a third via contact connecting the first phase shifter and the inductor that are electrically isolated by the insulating layer.

In further embodiments, the package structures may further include a Printed Circuit Board (PCB) substrate supported by the first substrate, an electrode pad on the PCB substrate, and a bonding wire connecting the electrode pad to the second via contact.

In still further embodiments, the PCB substrate may further include at least one of a second phase shifter and inductors.

In even further embodiments, the package structures may further include a PCB substrate facing the first substrate, an electrode pad on the PCB substrate, and a solder ball connecting the second via contact.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a circuit diagram illustrating a typical filter to described connection relation between various devices necessary for a package structure according to an embodiment;

FIG. 2 is a cross-sectional view illustrating a package structure according to an embodiment;

FIG. 3 is a cross-sectional view illustrating a package structure according to another embodiment; and

FIGS. 4 through 7 are cross-sectional views illustrating package structures according to still other embodiments.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the specification, it will be understood that when a layer (or film) is referred to as being ‘on’ another layer or substrate, it can be directly on the other layer or substrate, or intervening layers may also be present. Also, in the figures, the dimensions of layers and regions are exaggerated for clarity of illustration. Also, though terms like a first, a second, and a third are used to describe various regions and layers in various embodiments of the present invention, the regions and the layers are not limited to these terms. These terms are used only to discriminate one region or layer from another region or layer. An embodiment described and exemplified herein includes a complementary embodiment thereof.

Hereinafter, a package structure according to exemplary embodiments will be described in detain with reference to the accompanying drawings.

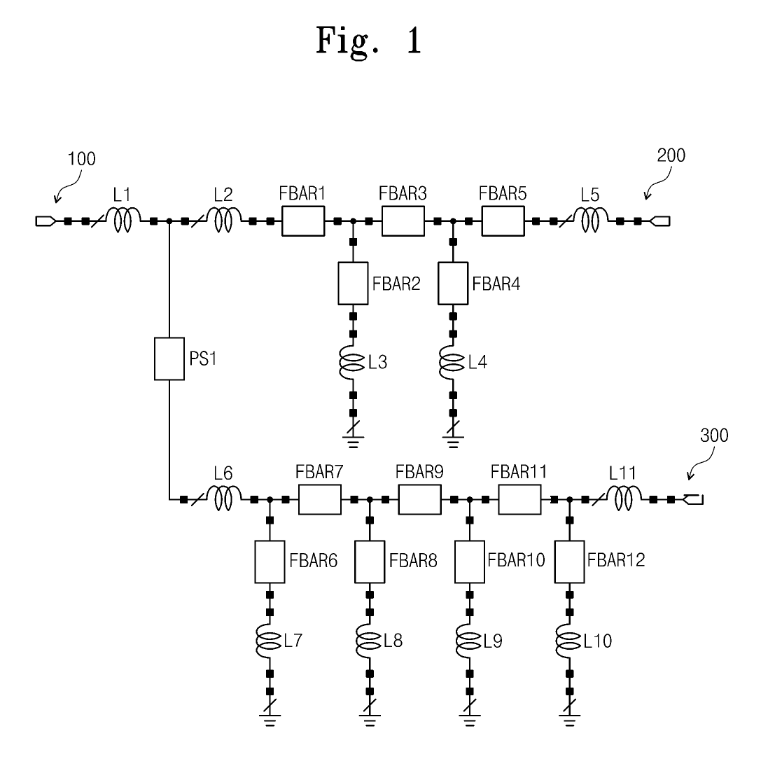

FIG. 1 is a circuit diagram illustrating a typical filter to describe connection relation between various devices necessary for a package structure according to an embodiment. The filter may include a combination of a plurality of inductors L1, L2, . . . , L11 and a plurality of resonators FBAR1, . . . , FBAR12, and a first phase shifter PS1 at a position divided into a sending end 200 and a receiving end 300. The filter serves as a duplexer that transmits/receives a transmitted wave and a received wave having different frequencies through a common antenna 100. When signals are transmitted and received, the first phase shifter PS1 can separate the received signal from signal processing by a phase difference to inhibit a received wave from flowing into a sending end 200.

Hereinafter, a package structure in which a resonator, an inductor, and a first phase shifter are combined and mounted according to an exemplary embodiment will be described in detail.

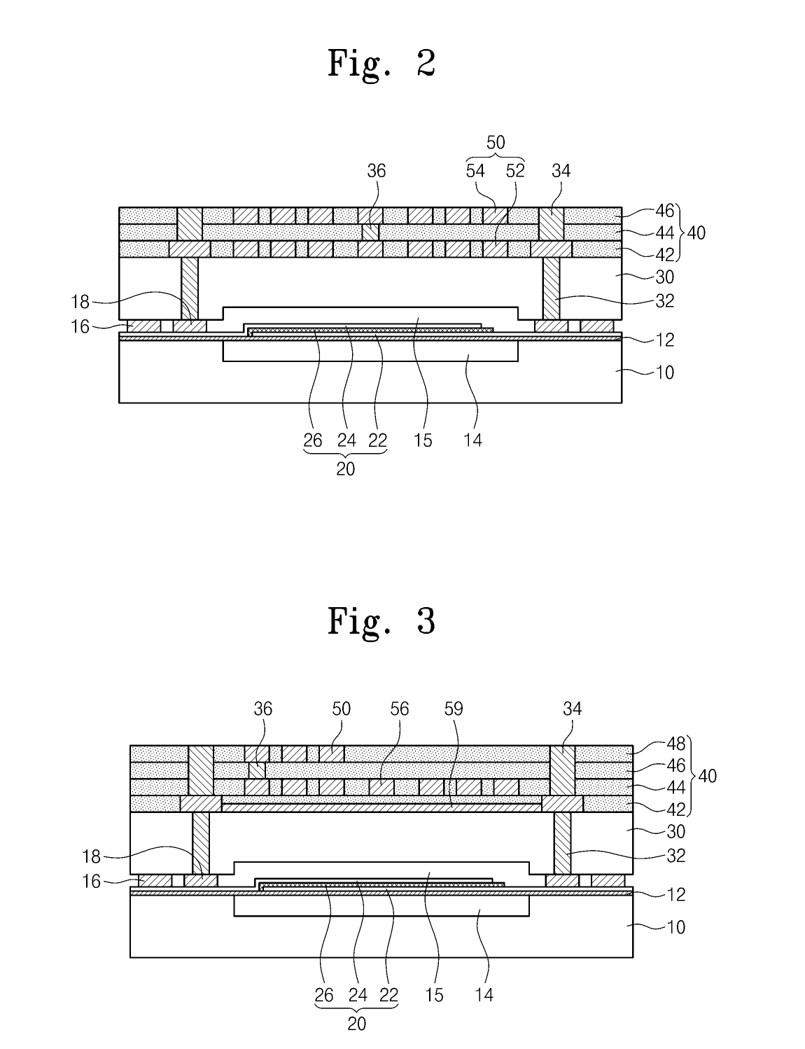

FIG. 2 is a cross-sectional view illustrating a package structure according to an embodiment.

Referring to FIG. 2, a package structure according to an embodiment may include a substrate 10, a resonator 20 on the substrate 10, a capping substrate 30 covering the resonator 20, and a plurality of inductors 50 stacked on the capping substrate 30. Here, the plurality of inductors 50 may be electrically connected to contact pads 18 on both sides of the substrate 10 through first via contacts 32. The contact pad 18 may be connected to a lower electrode 22 and an upper electrode 24 of the resonator 20 on the substrate 10. For example, two or more inductors 50 may be stacked on the capping substrate 30.

Accordingly, in the package structure according to the embodiment, at least one inductor 50 can be stacked on the capping substrate 30 covering the resonator 20 to minimize the size of a planar area in device integration.

The resonator 20, which is a device for generating or detecting oscillations or waves of specific frequencies using resonance phenomenon, may include a lower electrode 22, an upper electrode 24, and a piezoelectric material 26 between the lower and upper electrodes 22 and 24. The lower electrode 22 and upper electrode 24 may be isolated from the substrate 10 by an interlayer dielectric 12, and may include a metal material having excellent conductivity. The piezoelectric material 26 may allow a polarization to be induced therein when applied with an external mechanical pressure, or exhibit a mechanical modification by an external electric field. When applied with a weak current, the piezoelectric material 26 may be oscillated at a certain frequency according to the direction and size of a crystal. The piezoelectric material 26 can filter a wave of a specific frequency from the above oscillation. For example, the piezoelectric material 26 may include a material having a composition of Pb(Zr,Ti)03, which exhibits a PZT perovskite crystal structure.

The resonator 20 may be located at a certain height from the substrate 10 to generate a vertical oscillation in response to a frequency of an electrical signal applied from the outside. Accordingly, the resonator 20 may be formed on the interlayer dielectric 12 that is formed on the substrate 10, and may be supported by both edges of the substrate 10 on a trench 14. The trench 14 may be a void space formed by removing a sacrificial oxide that is previously formed under the resonator 20 and the interlayer dielectric layer 12.

Similarly, the resonator 20 may be spaced from the undersurface of the capping substrate 30 by more than a certain distance of an air gap 15 between the substrate 10 and the capping substrate 30. The substrate 10 and the capping substrate 30, which are first and second substrates, respectively, may have a resonator 20 interposed therebetween.

Contact pads 18 are formed on the upper electrode 24 and the lower electrode 22 extending to both sides of the resonator 20, respectively. Bonding pads 16 may be formed at outer sides of the contact pads 18 to bond the substrate 10 to the capping substrate 30. The contact pad 18 may be connected to a first via contact 32 penetrating through the capping substrate 30, and may be electrically connected to the plurality of inductors 50 over the capping substrate.

The inductor 50 may be a coil inducing a voltage in proportion to variation of a current. The inductor 50 may become a core component of a filter that inhibits a rapid change of the current and filters electrical noises to detect a frequency of a specific band. The plurality of inductors 50 may be stacked in an insulating layer 40. Insulators may be stacked in plurality between the plurality of inductors 50. For example, the insulating layer 40 may include a first insulating layer 42 insulating first inductors 52 on the capping substrate 30, a second insulating layer 44 on the first insulating layer 42, and a third insulating layer 46 insulating second inductors 54 on the second insulating layer 44. Accordingly, the plurality of inductors 50 may be connected to have a spiral pattern at the same level as the first and third insulating layers 42 and 46 as shown in FIG. 2.

The plurality of inductors 50 may be connected to the second via contact 34 penetrating through the second and third insulating layers 44 and 46 over the capping substrate 30 and extending to an upper part of the first via contact 32. Also, the plurality of inductors 50 may be connected to each other in series or in parallel by a third via contact 36 penetrating through the second insulating layer 44 over the resonator 20.

The plurality of inductors 50 may be formed over the capping substrate 30 after the capping substrate 30 is bonded to the substrate 10 on which the resonator 20 is formed. On the other hand, the substrate 10 and the capping substrate 30 may be bonded to each other after the resonator 20 and the plurality of inductors 50 are formed on the substrate 10 and the capping substrate 30 through different processes, respectively. In this case, the first via contact 32 may be formed through the capping substrate 30 before the plurality of inductors 50 are formed on the capping substrate 30.

In the package structure according to the first embodiment, since a variation of a planar area thereof can be minimized through a vertical integration of the resonator 20 and the inductors 50, micromini products can be realized.

Also, since an inductor having a higher Q than a typical inductor can be stacked on a capping substrate, an insertion loss of a filter can be reduced, and a high-performance device with a minimum area can be implemented.

FIG. 3 is a cross-sectional view illustrating a package structure according to another embodiment. A package structure according to another embodiment may include a ground electrode 59 on a capping substrate 30 covering a resonator, and a first phase shifter 56 and inductors 50 on the ground electrode 59.

The first phase shifter 56 may include a microstrip line that changes a phase of a received wave or a transmitted wave. The inductors 50 may be electrically isolated from the first phase shifter 56 by a third insulating layer 46, and may be electrically connected to the first phase shifter 56 through a third via contact 36. In this case, the positions of the first phase shifter 56 and the inductors 50 may be changed with each other, and lengths of the first phase shifter 56 and the inductors 50 may be variably formed respectively. An insulating layer 40 may include first to fourth insulating layers 42, 44, 45 and 48 for insulating the ground electrode 59, the first phase shifter 56, and the inductors 50 over the capping substrate 30.

In the package structure according to another embodiment, the first phase shifter 56 and the inductors 50 may be stacked on the capping substrate 30 covering the resonator 20, thereby minimizing the size of a planar area of the package structure.

The package structures according to the above embodiments may be formed through the following two methods.

First, a capping substrate 30 may be formed on a substrate 10 on which a resonator 20 is formed. A first via contact 32 may be formed to connect between the resonator 20 and an upper part of the capping substrate 30, and then a first phase shifter 56 and inductors 50 that are insulated by a second insulating layer 44 may be stacked on the capping substrate 30.

Second, a resonator 20 may be formed on a substrate 10, and then a first phase shifter 56 and inductors 50 may be formed on a capping substrate 30 in which a first via contact 32 is formed. Then, the substrate 10 and the capping substrate 30 are bonded to each other to electrically connect the resonator 20, the first phase shifter 56, and the inductors 50.

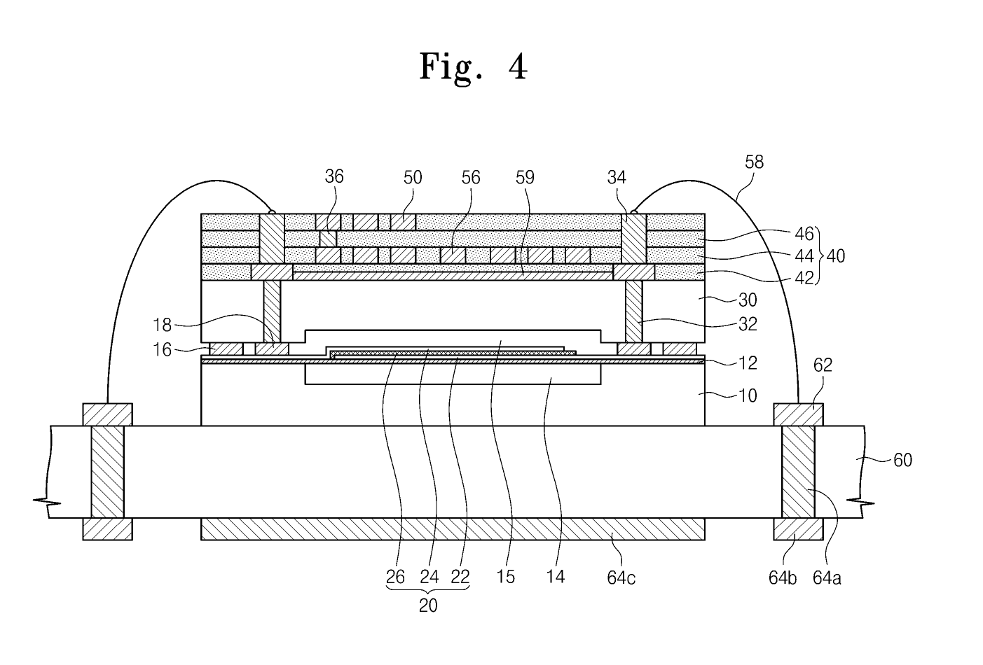

FIG. 4 is a cross-sectional view illustrating a package structure according to still another embodiment.

Referring to FIG. 4, a package structure according to still another embodiment may further include a PCB substrate 60, an electrode pad 62, and a bonding wire 58 in addition to the package structure according to the embodiment of FIG. 3. The substrate 10 including the package structure according to the embodiment of FIG. 3 is formed on the PCB substrate 60. The electrode pad 62 and the second via contact 34 may be connected through the bonding wire 58. Although not shown, the substrate 10 may include features of both the package structures according to the embodiments of FIGS. 2 and 3.

Here, the substrate 10 may be fixed on the PCB substrate 60 by an adhesive. At least two electrode pads 62 may be formed around the circumference of the substrate 10, and may be connected to the internal or lower interconnections 64a, 64b and 64c. Both ends of the bonding wire may be heated at a high temperature to be fixed on the electrode pad 62 and the via contact 34 by pressure. Although not shown, a second contact pad may be further formed to contact and fix the bonding wire 58 on an upper part of the second via contact 34. Furthermore, when a module including a resonator 20, inductors 50, and a first phase shifter 56 stacked therein is formed in plurality side by side on the PCB substrate 60, a multiband filter can be realized.

In the package structure according to still another embodiment, since the substrate 10 having the resonator 20 and the inductors 50 stacked thereon is fixed on the PCB substrate 60, and the devices formed on the substrate 10 are electrically connected to the PCB substrate 60 through the bonding wire 58, micromini products can be realized.

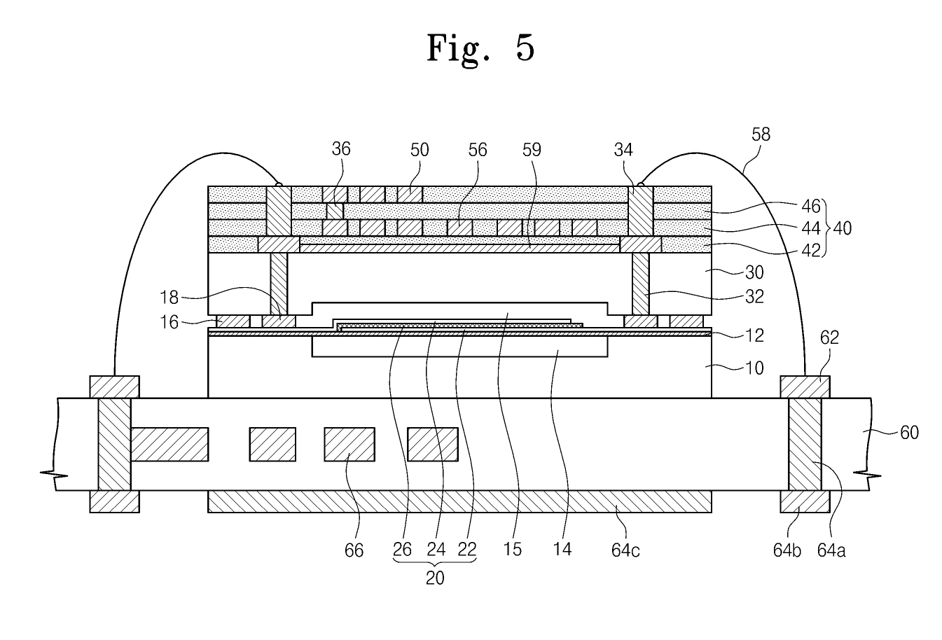

FIG. 5 is a cross-sectional view illustrating a package structure according to even another embodiment. In a package structure according to even another embodiment, a substrate 10 including the package structure according to the embodiment of FIG. 2 or 3 may be formed on a PCB substrate in which a second phase shifter 66 is formed, and then a bonding wire 58 may be connected between a second via contact 34 and an electrode pad 62.

In the package structure according to even another embodiment, since the second phase shifter 66 formed in the PCB substrate 60 is designed to be disposed under the substrate 10 having a resonator 20, inductors 50, and a first phase shifter 56 stacked therein, reduction of a planar area in integration of devices can realize micromini products.

Furthermore, since the second phase shifter 66 is formed in the PCB substrate 60 independently from the first phase shifter 56 over the substrate 10, a multiband filter capable of transmitting/receiving a plurality of frequencies can be realized.

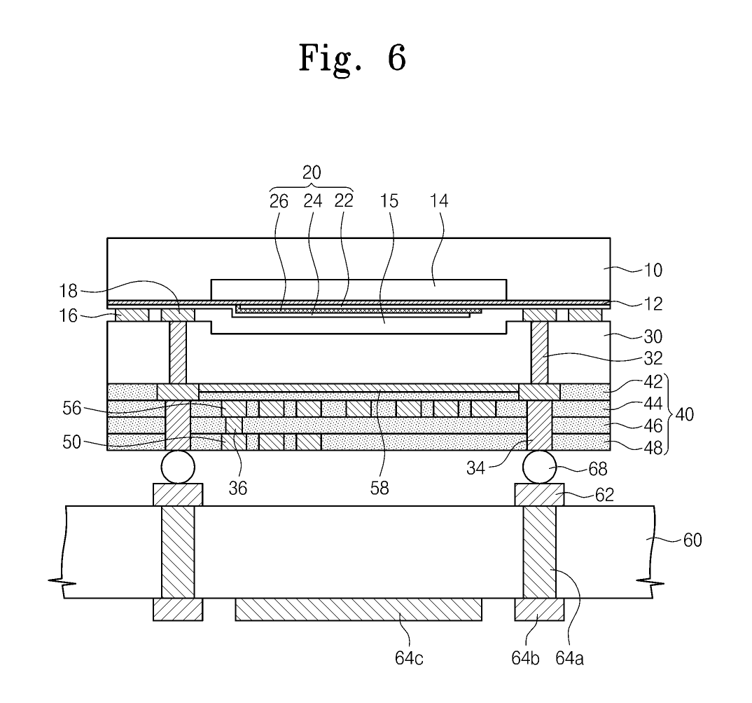

FIG. 6 is a cross-sectional view illustrating a package structure according to yet another embodiment.

Referring to FIG. 6, a package structure according to yet another embodiment may further include a solder ball 68. A second via contact 34 exposed on a substrate 10 on which the package structure according to the embodiment FIG. 2 or 3 is formed may be electrically connected to an electrode pad 62 formed on a PCB substrate 60 through the solder ball 68. The substrate 10 may be reversed such that a third insulating layer 46 and inductors 50 face the PCB substrate 60. The second via contact 34 and the electrode pad 62 may be formed on the substrate 10 and the PCB substrate in mutually corresponding sizes, respectively. At least two electrode pads 62 may be formed around the circumference of the substrate 10, and may be connected to the internal or lower interconnections 64a, 64b and 64c.

In the package structure according to yet another embodiment, since the substrate 10 having a resonator 20, a first phase shifter 56, and inductors 50 stacked thereon may be electrically connected to the PCB substrate 60 while facing the PCB substrate 60, micromini products can be realized.

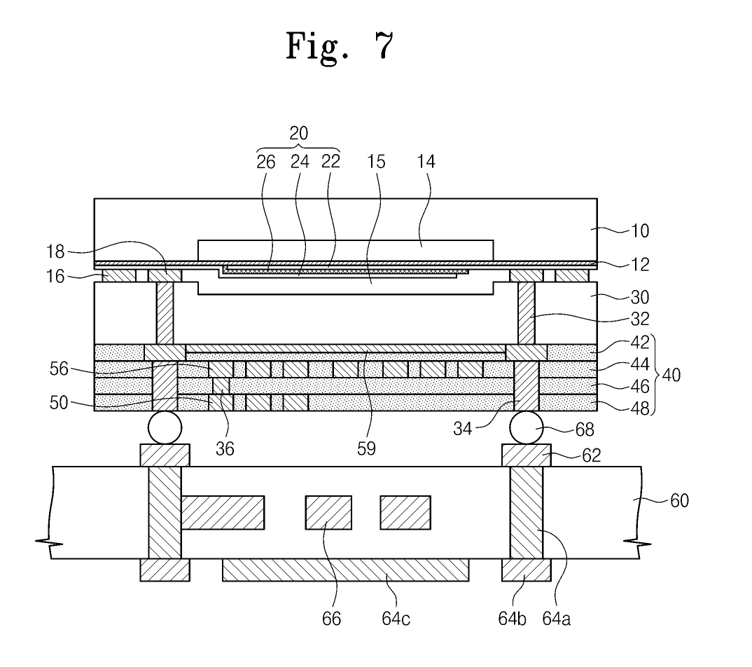

FIG. 7 is a cross-sectional view illustrating a package structure according to further another embodiment. In a package structure according to further another embodiment, a substrate 10 with the package structure according to the embodiment of FIG. 2 or 3 may be electrically connected to a PCB substrate 60 having a second phase shifter 66 therein through a solder ball 68 while facing the PCB substrate 60. Thus, a multiband filter can be implemented. Even if the volume of the package structure having a plurality of devices therein is increased, the size of an planar area that package structure occupies may not be increased.

In the package structure according to the embodiment, since the substrate 10 having a resonator 20, a first phase shifter 56, and inductors 50 stacked thereon is reversed to be fixed on the solder ball 68 over the second phase shifter 66 formed in the PCB substrate 60, the size of a planar area can be minimized in integration of devices.

Eventually, the package structures according to the embodiments can minimize the size of a planar area in integration of devices, and can reduce the manufacturing cost of components.

According to exemplary configuration of embodiments, micromini products can easily be implemented because a variation of a planar area is minimized by stacking an FBAR and an inductor.

Also, an inductor having a higher Q than that of a typical inductor is stacked in a capping substrate, thereby reducing an insertion loss of a filter and implementing a high performance device with a minimum area.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A package structure comprising:
a first substrate;
a first device on the first substrate;
a second substrate having an air gap over the first substrate and covering the first device;
a first via contact connected to the first device through the second substrate; and
at least one second device electrically connected to the first via contact and stacked on the second substrate.

2. The package structure of claim 1, further comprising a contact pad connecting the first device and the first via contact between the first substrate and the second substrate.

3. The package structure of claim 1, wherein the first device comprises a resonator, and the second device comprises at least one of an inductor or a first phase shifter.

4. The package structure of claim 3, further comprising an insulating layer electrically isolating the inductor from the first phase shifter.

5. The package structure of claim 4, further comprising a second via contact electrically connecting the first phase shifter and the inductor to the first via contact and exposed on an upper part of the insulating layer.

6. The package structure of claim 5, further comprising a third via contact connecting the first phase shifter and the inductor that are electrically isolated by the insulating layer.

7. The package structure of claim 5, further comprising a Printed Circuit Board (PCB) substrate supported by the first substrate, an electrode pad on the PCB substrate, and a bonding wire connecting the electrode pad to the second via contact.

8. The package structure of claim 7, wherein the PCB substrate further comprises at least one of a second phase shifter and inductors.

9. The package structure of claim 5, further comprising a PCB substrate facing the first substrate, an electrode pad on the PCB substrate, and a solder ball connecting the second via contact.

10. The package structure of claim 9, wherein the PCB substrate further comprises at least one of a second phase shifter and inductors.
